(19) United States
(12) Patent Application Publication
(10) Pub. No.: US 2026/0327248 A1
(43) Pub. Date: Oct. 22, 2026

(54) ALUMINUM PRECURSORS FOR DEPOSITION PROCESSES AND RELATED SYSTEMS AND RELATED METHODS

(71) Applicant: ENTEGRIS, INC., Billerica, MA (US)

(72) Inventor: Drew Michael Hood, Newtown, CT (US)

(21) Appl. No.: 19/577,202

(22) Filed: Mar. 24, 2026

Related U.S. Application Data
(60) Provisional application No. 63/776,936, filed on Mar. 24, 2025.

(51) Int. Cl. C07F 5/06

(52) U.S. Cl. CPC C07F 5/069

(57) ABSTRACT

Compositions comprising aluminum precursors for deposition processes, and related systems and related methods are provided. A composition comprises a precursor compound. The precursor compound comprises at least one of an aluminum halide precursor compound, an amino halide aluminum precursor compound, or any combination thereof, among others. Related methods for forming films using the compositions, including precursor compounds, and related systems are also provided herein, among other things.

### CROSS-REFERENCE TO RELATED APPLICATIONS

This application claims the benefit under 35 USC 119 of U.S. Provisional Patent Application No. 63/776,936, filed Mar. 24, 2025, the disclosure of which is hereby incorporated herein by reference in its entirety.

### FIELD

The present disclosure relates to aluminum precursors for deposition processes, and related systems and related methods.

### BACKGROUND

Vapor deposition processes can involve delivering precursors to tools. At the tool, the precursors are deposited onto a substrate.

### SUMMARY

Some embodiments relate to a composition. In some embodiments, the composition comprises a precursor compound of the formula:

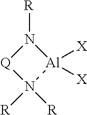

where:
each X independently comprises a halide;
each R independently comprises at least one of an alkyl, a cycloalkyl, an aryl, or any combination thereof; and
Q comprises —(CR¹R¹)ₙ—,
where:
each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
n is 1 to 10.

Some embodiments relate to a composition. In some embodiments, the composition comprises a precursor compound of the formula:

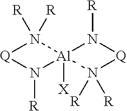

where:
X comprises a halide;
each R independently comprises at least one of an alkyl, a cycloalkyl, an aryl, or any combination thereof; and
Q independently comprises —(CR¹R¹)ₙ—,
where:
each R¹ independently comprises at least one of a hydrogen, an alkyl, a cycloalkyl, an aryl, an amino, or any combination thereof, or at least two R's are bonded to form at least one of a cycloalkyl, an aromatic ring, or any combination thereof; and
n is 1 to 10.

Some embodiments relate to a method. In some embodiments, the method comprises the step of obtaining a precursor compound. In some embodiments, the method comprises the step of vaporizing at least the precursor compound to obtain a vaporized precursor. In some embodiments, the method comprises the step of contacting a substrate with at least the vaporized precursor to form a film on the substrate. In some embodiments, the precursor compound comprises a compound of the formula:

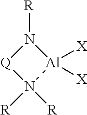

where:
each X independently comprises a halide;
each R independently comprises at least one of an alkyl, a cycloalkyl, an aryl, or any combination thereof; and
Q comprises —(CR¹R¹)ₙ—,
where:
each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
n is 1 to 10.

Some embodiments relate to a method. In some embodiments, the method comprises the step of obtaining a precursor compound. In some embodiments, the method comprises the step of vaporizing at least the precursor compound to obtain a vaporized precursor. In some embodiments, the method comprises the step of contacting a substrate with at least the vaporized precursor to form a film on the substrate. In some embodiments, the precursor compound comprises a compound of the formula:

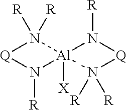

where:
X comprises a halide;
each R independently comprises at least one of an alkyl, a cycloalkyl, an aryl, or any combination thereof; and
Q independently comprises —(CR¹R¹)ₙ—,
where:
each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and n is 1 to 10.

### BRIEF DESCRIPTION OF THE DRAWINGS

FIG. 1 is a flowchart of a method of forming a film on a substrate, according to some embodiments.

FIG. 2 is a graphical view of a thermogravimetric analysis of the precursor compound, according to some embodiments.

FIG. 3 is a graphical view of a differential scanning calorimetry analysis of the precursor compound, according to some embodiments.

FIG. 4 is a graphical view of a thermogravimetric analysis of the precursor compound, according to some embodiments.

FIG. 5 is a graphical view of a differential scanning calorimetry analysis of the precursor compound, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

As used herein, the term “alkyl” refers to a hydrocarbyl having from 1 to 30 carbon atoms. In some embodiments, the alkyl is monovalent. For example, in some embodiments, the alkyl has a single point of attachment, -(alkyl). In some embodiments, the alkyl is divalent. For example, in some embodiments, the divalent has two points of attachment, -(alkyl)-. An alkyl having n carbon atoms may be designated as a “Cn alkyl.” For example, a “C₃ alkyl” may include n-propyl and isopropyl. An alkyl having a range of carbon atoms, such as 1 to 10 carbon atoms, may be designated as a C₁-C₁₀ alkyl. In some embodiments, the alkyl is linear. In some embodiments, the alkyl is branched. In some embodiments, the alkyl is a substituted alkyl. In some embodiments, the alkyl is an unsubstituted alkyl. In some embodiments, the alkyl comprises or is selected from the group consisting of at least one of a C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₁-C₂ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₉-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, or any combination thereof.

As used herein, the term “cycloalkyl” refers to a non-aromatic carbocyclic ring having from 3 to 10 carbon atoms in the ring. The term includes a monocyclic non-aromatic carbocyclic ring and a polycyclic non-aromatic carbocyclic ring. The term “monocyclic,” when used as a modifier, refers to a cycloalkyl having a single cyclic ring structure. The term “polycyclic,” when used as a modifier, refers to a cycloalkyl having more than one cyclic ring structure, which may be fused, bridged, spiro, or otherwise bonded ring structures. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, bicyclo[4,4,0]decane (decalin), bicyclo[4,3,0]nonane, or any combination thereof.

As used herein, the term “aryl” refers to a monocyclic or polycyclic aromatic hydrocarbon. The number of carbon atoms of the aryl may be in a range of 6 to 12 carbon atoms in the ring. The term “monocyclic,” when used as a modifier, refers to an aryl having a single aromatic ring structure. The term “polycyclic,” when used as a modifier, refers to an aryl having more than one aromatic ring structure, which may be fused, bridged, spiro, or otherwise bonded ring structures. In some embodiments, the aryl may comprise, consist of, or consist essentially of, or may be selected from the group consisting of, at least one naphtyl, tolyl, biphenyl, or any combination thereof.

As used herein, the term “amino” refers to a functional group of formula-N(R^{a}R^{b}), wherein R^{a} and R^{b} are independently a hydrogen, an alkyl (as defined herein), an aminoalkyl (as defined herein), or a silyl (as defined herein), or R^{a} and R^{b} are bonded to each other to form a C₃-C₂₀ N-heterocycle.

As used herein, the term “halide” refers to a —Cl, —Br, —I, or —F.

Aluminum precursors for deposition processes, and related systems and related methods, are provided. For example, aluminum precursors, such as, for example and without limitation, aluminum halides and mixed amino halide aluminum precursors, among others, for thin film deposition are provided. The aluminum precursors provided herein can be useful in the fabrication of microelectronic devices, such as, for example and without limitation, semiconductor devices, among others. The aluminum precursors provided herein can be non-pyrophoric. The aluminum precursors provided herein can include solid aluminum precursors and liquid aluminum precursors. For example, in some embodiments, the aluminum precursor is present as a low-melting solid—i.e., a solid having a melting point at or below the delivery temperature of a deposition process. In some embodiments, the aluminum precursor is present as a liquid at or below the delivery temperature of a deposition process. The aluminum precursors provided herein can further be useful for forming high quality films with low carbon incorporation, thereby resulting in low leakage current, among other things. The aluminum precursors provided herein can also be non-corrosive to stainless steel and other alloys and thus can obviate the need for protective coatings, among other things.

Some embodiments relate to a composition. In some embodiments, the composition comprises a precursor compound. In some embodiments, the precursor compound comprises at least one of an amino-halide aluminum precursor, a β-diketiminate-halide precursor, an amidinate-halide aluminum precursor, or any combination thereof, among others. In some embodiments, the precursor compound comprises a compound of the formula:

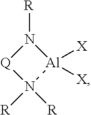

where:
each X independently comprises a halide;
each R independently comprises at least one of an alkyl, a cycloalkyl, an aryl, or any combination thereof; and
Q comprises —(CR¹R¹)ₙ—,
where:
each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
n is 1 to 10.

In some embodiments, each X is the same. In some embodiments, each X is different. In some embodiments, each R is the same. In some embodiments, at least two R is different. In some embodiments, each R is different.

In some embodiments, each R¹ is different. In some embodiments, each R¹ is the same.

In some embodiments, at least two R¹s are bonded to form at least one of a cycloalkyl, an aromatic ring, or any combination thereof. In some embodiments, the cycloalkyl or aromatic ring can be at least one of substituted, unsubstituted, or any combination thereof. In some embodiments, at least one of the type of substitution, the location of the substitution, the number of substitutions, or any combination thereof, can be varied to change at least one of the melting point of the precursor compound, the stability of the precursor compound, the amount of carbon in the resulting film from depositing the precursor compound, or any combination thereof. For example, in some embodiments, the location of the substitution can be varied to obtain a desired melting point of the precursor compound, the desired stability of the precursor compound, and the desired amount of carbon in the resulting film from depositing the precursor compound.

In some embodiments, n is 1 to 10, or any range or subrange between 1 to 10. For example, in some embodiments, n is 1 to 9, 1 to 8, 1 to 7, 1 to 6, 1 to 5, 1 to 4, 1 to 3, 1 to 2, 2 to 10, 3 to 10, 4 to 10, 5 to 10, 6 to 10, 7 to 10, 8 to 10, or 9 to 10.

In some embodiments, the precursor compound comprises a compound of the formula:

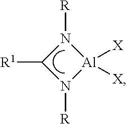

where:
each X independently comprises a halide;
each R comprises at least one of an alkyl, a cycloalkyl, an aryl, or any combination thereof; and
R¹ comprises at least one of an alkyl, a cycloalkyl, an aryl, an amino, or any combination thereof.
In some embodiments, each X is the same. In some embodiments, each X is different. In some embodiments, each R is the same. In some embodiments, at least two R is different. In some embodiments, each R is different. In some embodiments, R¹ and at least one R is the same. In some embodiments, R¹ and R are the same. In some embodiments, R¹ and at least one R are different. In some embodiments, R¹ and R are different.

In some embodiments, the precursor compound comprises a compound of the

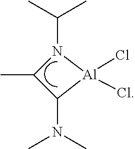

In some embodiments, the precursor compound comprises a compound of the formula:

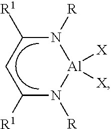

where:
each X independently comprises a halide;
each R independently comprises at least one of an alkyl, a cycloalkyl, an aryl, or any combination thereof; and
each R¹ independently comprises at least one of an alkyl, a cycloalkyl, an aryl, or any combination thereof.

In some embodiments, each X is the same. In some embodiments, each X is different. In some embodiments, each R is the same. In some embodiments, at least two R is different. In some embodiments, each R is different. In some embodiments, R¹ and at least one R is the same. In some embodiments, R¹ and R are the same. In some embodiments, R¹ and at least one R are different. In some embodiments, R¹ and R are different.

In some embodiments, an aromatic ring is fused to Q. For example, in some embodiments, the precursor compound comprises a compound of the formula:

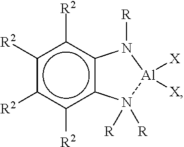

where:
each X independently comprises a halide;
each R independently comprises at least one of an alkyl, a cycloalkyl, an aryl, or any combination thereof; and
each R² independently comprises at least one of a hydrogen, an alkyl, a cycloalkyl, an aryl, or any combination thereof.

In some embodiments, the precursor compound comprises a compound of the

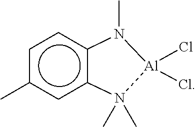

It will be appreciated that, although aromatic rings are shown above, cycloalkyl rings, either substituted or unsubstituted, can also be fused to Q without departing from the scope of this disclosure.

In some embodiments, the composition does not comprise a pyrophoric compound. In some embodiments, the pyrophoric compound comprises a trialkyl aluminum compound. In some embodiments, the pyrophoric compound comprises a trimethyl aluminum compound, a dimethyl aluminum chloride compound, a methyl lithium compound, or any combination thereof. Non-limiting examples of pyrophoric compounds include, for example and without limitation, at least one of trimethyl aluminum, dimethyl aluminum chloride, methyl lithium, or any combination thereof. It will be appreciated that the pyrophoric compound may include other types of pyrophoric compounds, without departing from the scope of this disclosure.

In some embodiments, the precursor compound is present as a liquid at temperatures in a range of 10° C. to 250° C. In some embodiments, the precursor compound is present as a liquid at a temperature in a range of 10° C. to 240° C., 10° C. to 230° C., 10° C. to 220° C., 10° C. to 210° C., 10° C. to 200° C., 10° C. to 190° C., 10° C. to 180° C., 10° C. to 170° C., 10° C. to 160° C., 10° C. to 150° C., 10° C. to 140° C., 10° C. to 130° C., 10° C. to 120° C., 10° C. to 110° C., 10° C. to 100° C., 10° C. to 90° C., 10° C. to 80° C., 10° C. to 70° C., 10° C. to 60° C., 10° C. to 50° C., 10° C. to 40° C., 10° C. to 30° C., 10° C. to 20° C., 20° C. to 250° C., 30° C. to 250° C., 40° C. to 250° C., 50° C. to 250° C., 60° C. to 250° C., 70° C. to 250° C., 80° C. to 250° C., 90° C. to 250° C., 100° C. to 250° C., 110° C. to 250° C., 120° C. to 250° C., 130° C. to 250° C., 140° C. to 250° C., 150° C. to 250° C., 160° C. to 250° C., 170° C. to 250° C., 180° C. to 250° C., 190° C. to 250° C., 200° C. to 250° C., 210° C. to 250° C., 220° C. to 250° C., 230° C. to 250° C., or 240° C. to 250° C. In some embodiments, the precursor compound is present as a liquid at room temperature.

In some embodiments, the precursor compound is present in the composition at a purity of 95% to 99.9999% as measured by 1H NMR. For example, in some embodiments, the precursor compound is present in the composition at a purity of 95% to 96%, 95% to 97%, 95% to 98%, 95% to 99%, 95% to 99.9%, 95% to 99.99%, 95% to 99.999%, 95% to 99.9999%, 96% to 99.9999%, 96% to 99.9999%, 97% to 99.9999%, 98% to 99.9999%, 99% to 99.9999%, 99.9% to 99.9999%, 99.99% to 99.9999%, or 99.999% to 99.9999%, as measured by 1H NMR.

Some embodiments relate to a composition. In some embodiments, the composition comprises a precursor compound of the formula:

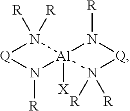

where:
X comprises a halide;
each R independently comprises at least one of an alkyl, a cycloalkyl, an aryl, or any combination thereof; and
each Q independently comprises —(CR¹R¹)ₙ—,
where:
each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
n is 1 to 10.

In some embodiments, each R is the same. In some embodiments, each R is different. In some embodiments, at least two Rs are different. In some embodiments, at least two Rs are the same. In some embodiments, each Q is the same. In some embodiments, each Q is different.

In some embodiments, each R¹ is different. In some embodiments, each R¹ is the same.

In some embodiments, at least two R¹s are bonded to form at least one of a cycloalkyl, an aromatic ring, or any combination thereof. In some embodiments, the cycloalkyl or aromatic ring can be at least one of substituted, unsubstituted, or any combination thereof. In some embodiments, at least one of the type of substitution, the location of the substitution, the number of substitutions, or any combination thereof, can be varied to change at least one of the melting point of the precursor compound, the stability of the precursor compound, the amount of carbon in the resulting film from depositing the precursor compound, or any combination thereof. For example, in some embodiments, the location of the substitution can be varied to obtain a desired melting point of the precursor compound, the desired stability of the precursor compound, and the desired amount of carbon in the resulting film from depositing the precursor compound.

In some embodiments, n is 1 to 10, or any range or subrange between 1 to 10. For example, in some embodiments, n is 1 to 9, 1 to 8, 1 to 7, 1 to 6, 1 to 5, 1 to 4, 1 to 3, 1 to 2, 2 to 10, 3 to 10, 4 to 10, 5 to 10, 6 to 10, 7 to 10, 8 to 10, or 9 to 10.

In some embodiments, the precursor compound comprises a compound of a formula:

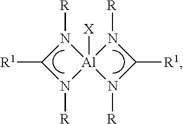

where:
X comprises a halide;
each R independently comprises at least one of an alkyl, a cycloalkyl, an aryl, or any combination thereof; and
each R¹ independently comprises at least one of an alkyl, a cycloalkyl, an aryl, an amino, or any combination thereof.

In some embodiments, each R is the same. In some embodiments, each R is different. In some embodiments, at least two Rs are different. In some embodiments, at least two Rs are the same. In some embodiments, each R¹ is the same. In some embodiments, each R¹ is different. In some embodiments, at least one R¹ and at least one R are the same. In some embodiments, at least one R¹ and at least one R are different.

In some embodiments, the precursor compound comprises a compound of the formula:

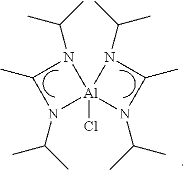

In some embodiments, the precursor compound comprises a compound of the formula:

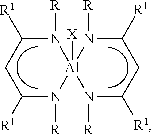

where:
X comprises a halide;
each R independently comprises at least one of an alkyl, a cycloalkyl, an aryl, or any combination thereof; and
each R¹ independently comprises at least one of an alkyl, a cycloalkyl, an aryl, or any combination thereof.

In some embodiments, an aromatic ring is fused to Q. For example, in some embodiments, the precursor compound comprises a compound of the formula:

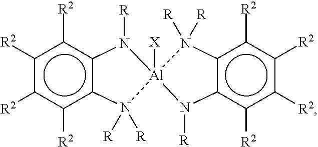

where:
X comprises a halide;
each R independently comprises at least one of an alkyl, a cycloalkyl, an aryl, or any combination thereof; and
each R² independently comprises at least one of a hydrogen, an alkyl, a cycloalkyl, an aryl, or any combination thereof.

In some embodiments, the precursor compound comprises a compound of the formula:

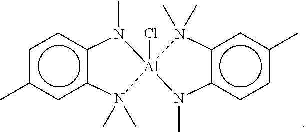

It will be appreciated that, although aromatic rings are shown above, cycloalkyl rings, either substituted or unsubstituted, can also be fused to Q without departing from the scope of this disclosure.

In some embodiments, the composition does not comprise a pyrophoric compound. In some embodiments, the pyrophoric compound comprises a trialkyl aluminum compound. In some embodiments, the pyrophoric compound comprises a trimethyl aluminum compound, a dimethyl aluminum chloride compound, a methyl lithium compound, or any combination thereof. Non-limiting examples of pyrophoric compounds include, for example and without limitation, at least one of trimethyl aluminum, dimethyl aluminum chloride, methyl lithium, or any combination thereof. It will be appreciated that the pyrophoric compound may include other types of pyrophoric compounds, without departing from the scope of this disclosure.

In some embodiments, the precursor compound is present as a liquid at temperatures in a range of 10° C. to 250° C. In some embodiments, the precursor compound is present as a liquid at a temperature in a range of 10° C. to 240° C., 10° C. to 230° C., 10° C. to 220° C., 10° C. to 210° C., 10° C. to 200° C., 10° C. to 190° C., 10° C. to 180° C., 10° C. to 170° C., 10° C. to 160° C., 10° C. to 150° C., 10° C. to 140° C., 10° C. to 130° C., 10° C. to 120° C., 10° C. to 110° C., 10° C. to 100° C., 10° C. to 90° C., 10° C. to 80° C., 10° C. to 70° C., 10° C. to 60° C., 10° C. to 50° C., 10° C. to 40° C., 10° C. to 30° C., 10° C. to 20° C., 20° C. to 250° C., 30° C. to 250° C., 40° C. to 250° C., 50° C. to 250° C., 60° C. to 250° C., 70° C. to 250° C., 80° C. to 250° C., 90° C. to 250° C., 100° C. to 250° C., 110° C. to 250° C., 120° C. to 250° C., 130° C. to 250° C., 140° C. to 250° C., 150° C. to 250° C., 160° C. to 250° C., 170° C. to 250° C., 180° C. to 250° C., 190° C. to 250° C., 200° C. to 250° C., 210° C. to 250° C., 220° C. to 250° C., 230° C. to 250° C., or 240° C. to 250° C. In some embodiments, the precursor compound is present as a liquid at room temperature.

In some embodiments, the precursor compound is present in the composition at a purity of 95% to 99.9999% as measured by 1H NMR. For example, in some embodiments, the precursor compound is present in the composition at a purity of 95% to 96%, 95% to 97%, 95% to 98%, 95% to 99%, 95% to 99.9%, 95% to 99.99%, 95% to 99.999%, 95% to 99.9999%, 96% to 99.9999%, 96% to 99.9999%, 97% to 99.9999%, 98% to 99.9999%, 99% to 99.9999%, 99.9% to 99.9999%, 99.99% to 99.9999%, or 99.999% to 99.9999%, as measured by 1H NMR.

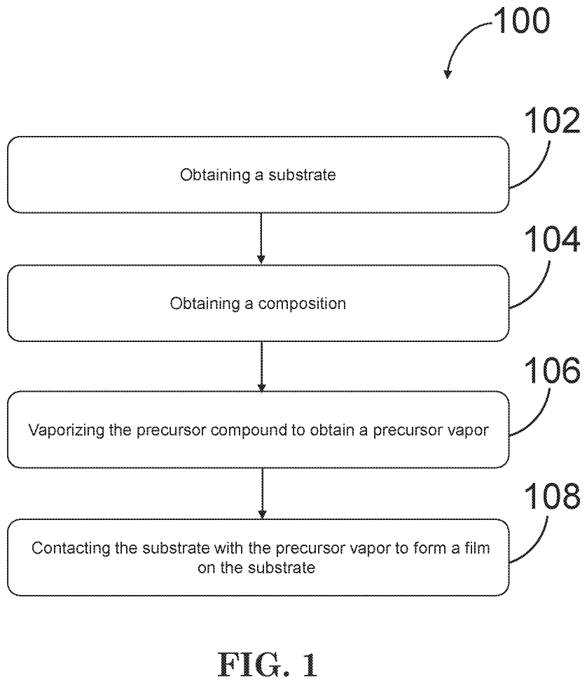

FIG. 1 is a flowchart of a method of forming a film on a substrate, according to some embodiments. As shown in FIG. 1, the method 100 comprises one or more of the following steps: obtaining 102 a precursor compound, vaporizing 104 at least the precursor compound to obtain a vaporized precursor; and contacting 106 a substrate with at least the vaporized precursor to form a film on the substrate.

At step 102, in some embodiments, the method comprises obtaining a precursor compound.

In some embodiments, the obtaining comprises obtaining a vessel comprising the precursor compound. In some embodiments, the obtaining comprises obtaining a container comprising the precursor compound. In some embodiments, the precursor compound may be obtained in a container or other vessel in which the precursor is to be vaporized.

The precursor compound may comprise any one or more of the precursor compounds disclosed herein. For example, in some embodiments, the precursor compound comprises a compound of the formula:

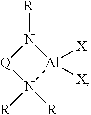

where:
each X independently comprises a halide;
each R independently comprises at least one of an alkyl, a cycloalkyl, an aryl, or any combination thereof; and
Q comprises —(CR¹R¹)ₙ—,
where:
each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
n is 1 to 10.

In some embodiments, the precursor compound comprises a compound of the

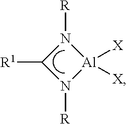

where:
each X independently comprises a halide;
each R comprises at least one of an alkyl, a cycloalkyl, an aryl, or any combination thereof; and
each R¹ comprises at least one of an alkyl, a cycloalkyl, an aryl, an amino, or any combination thereof.

In some embodiments, the precursor compound comprises a compound of the formula:

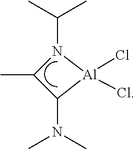

In some embodiments, the precursor compound comprises a compound of the

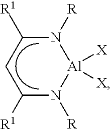

where:
each X independently comprises a halide;
each R independently comprises at least one of an alkyl, a cycloalkyl, an aryl, or any combination thereof; and
each R¹ independently comprises at least one of an alkyl, a cycloalkyl, an aryl, or any combination thereof.

In some embodiments, an aromatic ring is fused to Q. For example, in some embodiments, the precursor compound comprises a compound of the formula:

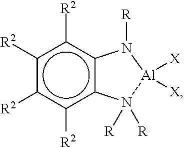

where:
each X independently comprises a halide;
each R independently comprises at least one of an alkyl, a cycloalkyl, an aryl, or any combination thereof; and
each R² independently comprises at least one of a hydrogen, an alkyl, a cycloalkyl, an aryl, or any combination thereof.

In some embodiments, the precursor compound comprises a compound of the formula:

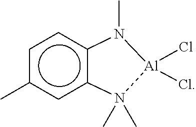

It will be appreciated that, although aromatic rings are shown above, cycloalkyl rings, either substituted or unsubstituted, can also be fused to Q without departing from the scope of this disclosure.

In some embodiments, the composition comprises a precursor compound of the formula:

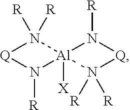

where:
X comprises a halide;
each R independently comprises at least one of an alkyl, a cycloalkyl, an aryl, or any combination thereof; and
each Q independently comprises —(CR¹R¹)ₙ—,
where:
each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and n is 1 to 10.

In some embodiments, the precursor compound comprises a compound of a formula:

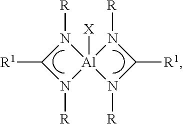

where:
X comprises a halide;
each R independently comprises at least one of an alkyl, a cycloalkyl, an aryl, or any combination thereof; and
each R¹ independently comprises at least one of an alkyl, a cycloalkyl, an aryl, an amino, or any combination thereof.

In some embodiments, the precursor compound comprises a compound of the formula:

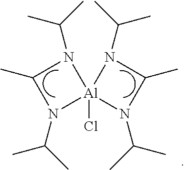

In some embodiments, the precursor compound comprises a compound of the formula:

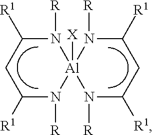

where:
X comprises a halide;
each R independently comprises at least one of an alkyl, a cycloalkyl, an aryl, or any combination thereof; and
each R¹ independently comprises at least one of an alkyl, a cycloalkyl, an aryl, or any combination thereof.

In some embodiments, the precursor compound comprises a compound of the

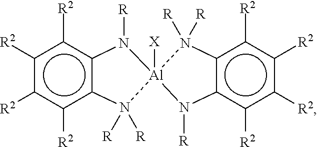

where:
X comprises a halide;
each R independently comprises at least one of an alkyl, a cycloalkyl, an aryl, or any combination thereof; and
each R² independently comprises at least one of a hydrogen, an alkyl, a cycloalkyl, an aryl, or any combination thereof.

In some embodiments, the precursor compound comprises a compound of the

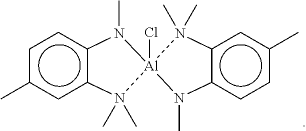

It will be appreciated that, although aromatic rings are shown above, cycloalkyl rings, either substituted or unsubstituted, can also be fused to Q without departing from the scope of this disclosure.

At step 104, in some embodiments, the method comprises vaporizing at least the precursor compound to obtain a vaporized precursor.

In some embodiments, the vaporizing may comprise heating at least the precursor compound sufficient to obtain the vaporized precursor. In some embodiments, the vaporizing comprises heating at least a container comprising the precursor compound. In some embodiments, the vaporizing comprises heating at least the precursor compound in a deposition chamber in which the vapor deposition process is performed. In some embodiments, the vaporizing comprises heating at least a conduit for delivering the precursor compound, the vaporized precursor, or any combination thereof to, for example, a deposition chamber. In some embodiments, the vaporizing comprises operating at least a vapor delivery system comprising the precursor compound. In some embodiments, the vaporizing comprises heating at least to a temperature sufficient to vaporize the precursor compound to obtain the vaporized precursor. In some embodiments, the vaporizing comprises heating at least to a temperature below a decomposition temperature of at least one of the precursor compound, the precursor compound, or any combination thereof.

The vapor deposition conditions may comprise conditions for vapor deposition processes. Examples of vapor deposition conditions include, without limitation, vapor deposition conditions for vapor deposition processes including at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The vapor deposition conditions may comprise a deposition temperature. The deposition temperature may be a temperature less than the thermal decomposition temperature of the vaporized precursor. The deposition temperature may be sufficiently high to reduce or avoid condensation of the vaporized precursor. In some embodiments, the substrate may be heated to the deposition temperature. In some embodiments, the chamber or other vessel in which the substrate is contacted with the vaporized precursor is heated to the deposition temperature. In some embodiments, the vaporized precursor may be heated to the deposition temperature.

The deposition temperature may be a temperature of 150° C. to 1000° C., or any range or subrange between 150° C. and 1000° C. For example, in some embodiments, the deposition temperature may be a temperature of 200° C. and 1000° C., 300° C. and 1000° C., 400° C. and 1000° C., 500° C. and 1000° C., 600° C. and 1000° C., 700° C. and 1000° C., 800° C. and 1000° C., 900° C. and 1000° C., 150° C. to 900° C., 150° C. to 800° C., 150° C. to 700° C., 150° C. to 600° C., 150° C. to 500° C., 150° C. to 400° C., 150° C. to 300° C., or 150° C. to 200° C.

The vapor deposition conditions may comprise a deposition pressure. In some embodiments, the deposition pressure may comprise a vapor pressure of vaporized precursor. In some embodiments, the deposition pressure may comprise a chamber pressure.

The deposition pressure may be a pressure of 0.001 Torr to 100 Torr, or any range or subrange between 0.001 Torr and 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 m Torr to 100 m Torr, 1 m Torr to 90 mTorr, 1 mTorr to 80 m Torr, 1 mTorr to 70 mTorr, 1 m Torr to 60 mTorr, 1 mTorr to 50 m Torr, 1 mTorr to 40 mTorr, 1 m Torr to 30 mTorr, 1 m Torr to 20 m Torr, 1 m Torr to 10 m Torr, 100 m Torr to 300 m Torr, 150 m Torr to 300 m Torr, 200 m Torr to 300 m Torr, or 150 m Torr to 250 m Torr, or 150 m Torr to 225 m Torr.

At step 106, in some embodiments, the method comprises contacting a substrate with at least the vaporized precursor to form a film on the substrate.

In some embodiments, the contacting may comprise proceed under vapor deposition conditions. In some embodiments, the contacting comprises bringing the vaporized precursor and the substrate into close or immediate proximity to form a film on the substrate. In some embodiments, the contacting comprises bringing the substrate and the vaporized precursor into direct physical contact to form a film on the substrate. In some embodiments, the contacting comprises flowing the vaporized precursor over the substrate to form a film on the substrate. In some embodiments, the contacting comprises pumping the vaporized precursor to a deposition chamber. In some embodiments, the contacting comprises supplying the vaporized precursor to a deposition chamber. In some embodiments, the contacting comprises heating the vaporized precursor to maintain the precursor in a vapor phase. In some embodiments, the contacting comprises delivering the vaporized precursor to a deposition chamber.

In some embodiments, the substrate may comprise at least one of Si, Co, Cu, Al, W, WN, WC, TiN, Mo, MOC, SiO₂, W, SiN, WCN, Al₂O₃, AlN, ZrO₂, La₂O₃, TaN, RuO₂, IrO₂, Nb₂a₃, Y₂O₃, hafnium oxide, or any combination thereof.

In some embodiments, the film has a thickness of 0.1 nm to 1000 nm, or any range or subrange between 0.1 nm to 1000 nm. For example, in some embodiments, the film has a thickness of 0.1 nm to 900 nm, 0.1 nm to 800 nm, 0.1 nm to 700 nm, 0.1 nm to 600 nm, 0.1 nm to 500 nm, 0.1 nm to 400 nm, 0.1 nm to 300 nm, 0.1 nm to 200 nm, 0.1 nm to 100 nm, 0.1 nm to 10 nm, 0.1 nm to 1 nm, 10 nm to 1000 nm, 100 nm to 1000 nm, 200 nm to 1000 nm, 300 nm to 1000 nm, 400 nm to 1000 nm, 500 nm to 1000 nm, 600 nm to 1000 nm, 700 nm to 1000 nm, 800 nm to 1000 nm, or 900 nm to 1000 nm.

In some embodiments, when the precursor compounds disclosed herein are used in a deposition process (e.g., a vapor deposition process) to produce a film on a substrate (e.g., a thin film on a substrate), the resulting film can be formed with low carbon incorporation. In some embodiments, the film has a carbon content of less than 5% by weight based on a total weight of the film. In some embodiments, for example, the film has a carbon content of 0.1% to 5% by weight based on a total weight of the film, or any range or subrange between 0.1% and 5%. For example, in some embodiments, the film has a carbon content of less than 10% by weight based on a total weight of the film. In some embodiments, the film has a carbon content of 0.01% to 5%, 0.01% to 4%, 0.01% to 3%, 0.01% to 2%, 0.01% to 1%, 1% to 5%, 2% to 5%, 3% to 5%, or 4% to 5%, by weight based on a total weight of the film.

Any one or more of the embodiments disclosed herein shall be understood to be combinable without departing from the scope or spirit of the disclosure.

### Example 1

In a nitrogen filled glovebox, 0.50 g of Li[MeC(NiPr)₂] (3.375 mmol, 1 eq) was added to a 40 mL vial. A stir bar and 15 mL of diethyl ether was also added to the 40 mL vial to create a slurry. The slurry was stirred while a solution of AlCl₃ (0.45 g, 3.375 mmol) in diethyl ether (15 mL) was added dropwise over the course of 30 mins. The resulting reaction mixture was allowed to stir overnight. Volatiles from the reaction mixture were removed under vacuum to produce a product. The product was extracted with 50 mL of pentane. The pentane solution was filtered before removing the solvent under vacuum to yield a crude product material as a white solid. The crude product material was purified by sublimation (40° C., 200 m Torr) to yield the precursor compound of {MeC(NiPr)₂}AlCl₂ as a white powder (0.38 g, 46%).

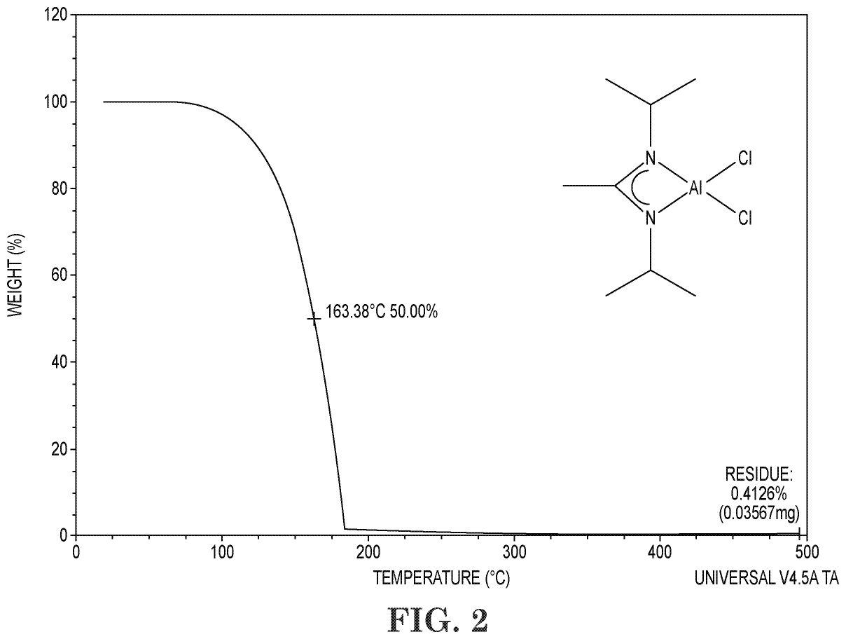

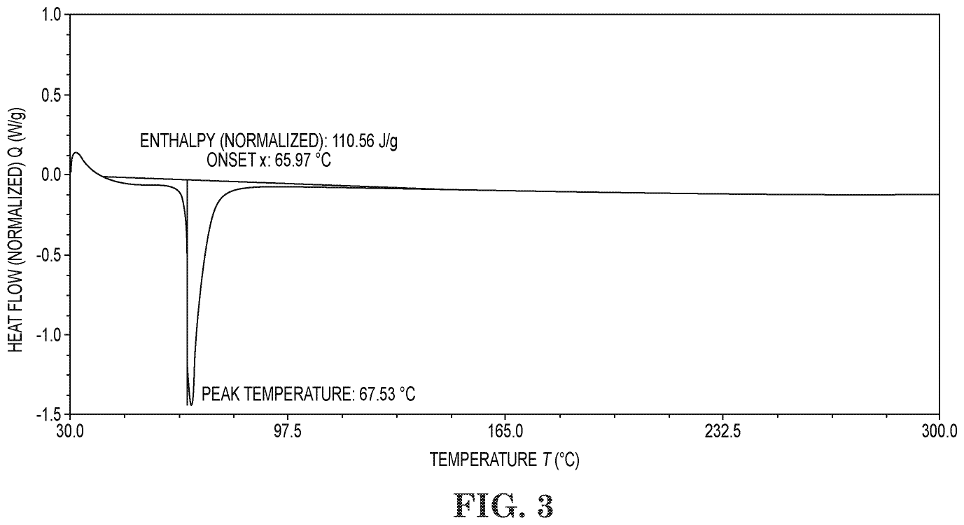

The white powder was measured using NMR and was observed to have the following chemical shifts: ¹H NMR (C₆D₆): δ 2.88 (sept., 2H, CHMe₂), 1.01 (s, 3H, CMe), 0.90 (d, 6H, CHMe₂). The monoamidinate species was confirmed by quantitative Nuclear Magnetic Resonance (qNMR) using tetramethylsilane (TMS) as an internal standard. The purity of {MeC(NiPr)₂}AlCl₂ was analyzed by thermogravimetric analysis (TGA) analysis using a ramp rate of 10° C./min up to 500° C. starting at room temperature. The TGA analysis showed a T_{1/2} of 163.4° C. and a residue 0.4%. The composition is a liquid at a temperature of 100° C. to 240° C. See FIG. 2 which is a graphical view of a thermogravimetric analysis of the precursor compound, according to some embodiments. In addition, the precursor compound was determined to have a melting point of 67.53° C. as measured according to a “close pan” Differential Scanning calorimetry (DSC) analysis (FIG. 3).

### Example 2

In a nitrogen filled glovebox, 1.00 g of Li[MeC(NiPr)₂] (6.75 mmol, 2 eq) was added to a 40 mL vial. A stir bar and 25 mL of diethyl ether was also added to the 40 mL vial to create a slurry. The slurry was stirred while a solution of AlCl₃ (0.45 g, 3.375 mmol) in diethyl ether (15 mL) was added dropwise over the course of 30 mins. The resulting reaction mixture was allowed to stir overnight. The volatiles from the reaction mixture were removed under reduced pressure to form a product. The product extracted with 50 mL of pentane. The pentane solution was filtered before removing the solvent under vacuum to yield a crude product material as a white solid. The crude product material was purified by distillation with a pot temperature of 130° C., at a baseline pressure of 200 mTorr. A condenser heated to 75° C. to yield the precursor compound of {MeC(NiPr)₂}2AlCl as a low melting white solid (0.49 g, 42%).

The low melting white solid was characterized using NMR spectroscopy and was observed to have the following chemical shifts: ¹H NMR (C₆D₆): δ 3.37 (sept., 2H, CHMe₂), 1.44 (s, 3H, CMe), 1.24 (d, 6H, CHMe₂). The bisamidinate species was confirmed by qNMR using tetramethylsilane (TMS) as an internal standard. The purity of {MeC(NiPr)₂}2AlCl was analyzed by TGA analysis using a ramp rate of 10° C./min up to 500° C. starting at room temperature.

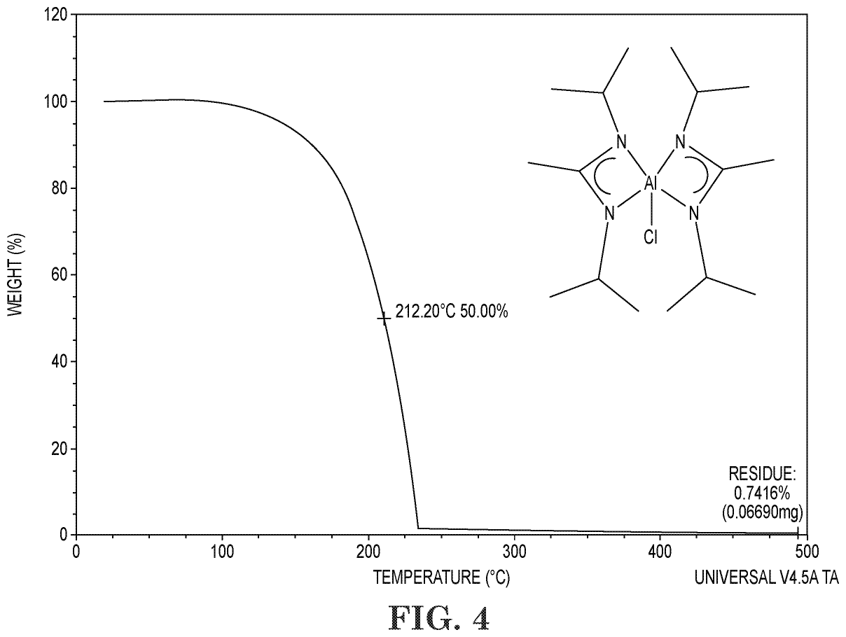

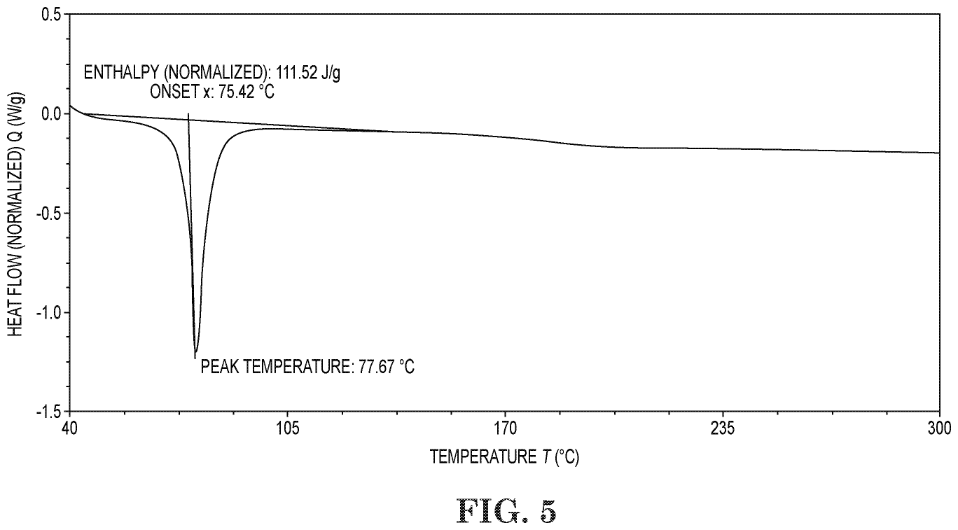

The TGA analysis showed a Tin of 212.2° C. and a residue 0.7%. The composition is a liquid at a temperature of 100° C. to 240° C. See FIG. 4 which is a graphical view of a thermogravimetric analysis of the precursor compound of formula (II), according to some embodiments. In addition, the precursor compound was determined to have a melting point of 77.67° C. as measured according to a “close pan” Differential Scanning calorimetry (DSC) analysis (FIG. 5).

### ASPECTS

Various Aspects are described below. It is to be understood that any one or more of the features recited in the following Aspect(s) can be combined with any one or more other Aspect(s).
Aspect 1. A composition comprising:
   a precursor compound of the formula:
      where:

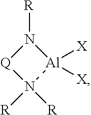

each X independently comprises a halide;
each R independently comprises at least one of an alkyl, a cycloalkyl, an aryl, or any combination thereof; and
Q comprises —(CR¹R¹)ₙ—,
where:
each R′ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
n is 1 to 10.
Aspect 2. The composition according to Aspect 1, wherein the composition does not comprise a pyrophoric compound.
Aspect 3. The composition according to any one of Aspects 1-2, wherein the precursor compound is present as a liquid at temperatures in a range of 10° C. to 200° C.
Aspect 4. The composition according to any one of Aspects 1-3, wherein the precursor compound is present in the composition at a purity of 95% to 99.999% as measured by 1H NMR.
Aspect 5. The composition according to any one of Aspects 1-4, wherein the precursor compound comprises a compound of the formula:
   where:

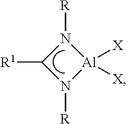

X independently comprises a halide;
each R comprises at least one of an alkyl, a cycloalkyl, an aryl, or any combination thereof; and
R¹ comprises at least one of an alkyl, a cycloalkyl, an aryl, an amino, or any combination thereof.
Aspect 6. The composition according to any one of Aspects 1-5, wherein the precursor compound comprises a compound of the formula:

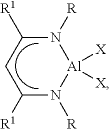

where:
   each X independently comprises a halide;
   each R independently comprises at least one of an alkyl, a cycloalkyl, an aryl, or any combination thereof; and
   each R¹ independently comprises at least one of an alkyl, a cycloalkyl, an aryl, or any combination thereof.
Aspect 7. A composition comprising:
   a precursor compound of the formula:

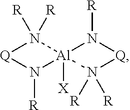

where:
   X comprises a halide;
   each R independently comprises at least one of an alkyl, a cycloalkyl, an aryl, or any combination thereof; and
   each Q independently comprises —(CR¹R¹)ₙ—,
   where:
   each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
   n is 1 to 10.
Aspect 8. The composition according to Aspect 7, wherein the composition does not comprise a pyrophoric compound.
Aspect 9. The composition according to any one of Aspects 7-8, wherein the precursor compound is present as a liquid at temperatures in a range of 10° C. to 200° C.
Aspect 10. The composition according to any one of Aspects 7-9, wherein the precursor compound is present in the composition at a purity of 95% to 99.999% as measured by 1H NMR.
Aspect 11. The composition according to any one of Aspects 7-10, wherein the precursor compound comprises a compound of a formula:

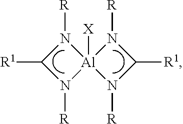

where:
   X comprises a halide;
   each R independently comprises at least one of an alkyl, a cycloalkyl, an aryl, or any combination thereof; and
   each R¹ independently comprises at least one of an alkyl, a cycloalkyl, an aryl, an amino, or any combination thereof.
Aspect 12. The composition according to any one of Aspects 7-11, wherein the precursor compound comprises a compound of the formula:

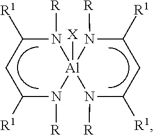

where:
   X comprises a halide;
   each R independently comprises at least one of an alkyl, a cycloalkyl, an aryl, or any combination thereof; and
   each R¹ independently comprises at least one of an alkyl, a cycloalkyl, an aryl, or any combination thereof.
Aspect 13. A method comprising:
   obtaining a precursor compound,
      wherein the precursor compound comprises a compound of the

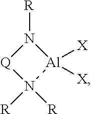

where:
X independently comprises a halide;
each R independently comprises at least one of an alkyl, a cycloalkyl, an aryl, or any combination thereof; and
Q comprises —(CR¹R¹)ₙ—,
where:
each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
n is 1 to 10;
vaporizing at least the precursor compound to obtain a vaporized precursor; and
contacting a substrate with at least the vaporized precursor to form a film on the substrate.
Aspect 14. The method according to Aspect 13, wherein, prior to the step of vaporizing, the precursor compound is present as a liquid.
Aspect 15. The method according to any one of Aspects 13-14, wherein the precursor compound comprises a compound of the formula:

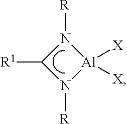

where:
   each X independently comprises a halide;
   each R comprises at least one of an alkyl, a cycloalkyl, an aryl, or any combination thereof; and
   R¹ comprises at least one of an alkyl, a cycloalkyl, an aryl, an amino, or any combination thereof.
Aspect 16. The method according to any one of Aspects 13-15, wherein the precursor compound comprises a compound of the formula:

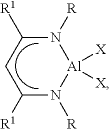

where:
   each X independently comprises a halide;
   each R independently comprises at least one of an alkyl, a cycloalkyl, an aryl, or any combination thereof; and
   each R¹ independently comprises at least one of an alkyl, a cycloalkyl, an aryl, or any combination thereof.
Aspect 17. A method comprising:
   obtaining a precursor compound,
      wherein the precursor compound comprises a compound of the formula:

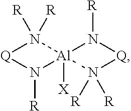

where:
X comprises a halide;
each R independently comprises at least one of an alkyl, a cycloalkyl, an aryl, or any combination thereof; and
each Q independently comprises —(CR¹R¹)ₙ—,
where:
each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
n is 1 to 10;
vaporizing at least the precursor compound to obtain a vaporized precursor; and
contacting a substrate with at least the vaporized precursor to form a film on the substrate.
Aspect 18. The method according to Aspect 17, wherein, prior to the step of vaporizing, the precursor compound is present as a liquid.
Aspect 19. The method according to any one of Aspects 17-18, wherein the precursor compound comprises a compound of a formula:

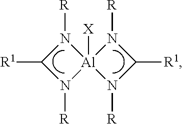

where:
   X comprises a halide;
   each R independently comprises at least one of an alkyl, a cycloalkyl, an aryl, or any combination thereof; and
   each R¹ independently comprises at least one of an alkyl, a cycloalkyl, an aryl, an amino, or any combination thereof.
Aspect 20. The method according to any one of Aspects 17-19, wherein the precursor compound comprises a compound of the formula:

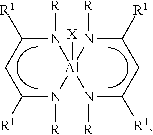

where:
   X comprises a halide;
   each R independently comprises at least one of an alkyl, a cycloalkyl, an aryl, or any combination thereof; and
   each R¹ independently comprises at least one of an alkyl, a cycloalkyl, an aryl, or any combination thereof.

What is claimed is:

1. A composition comprising:
a precursor compound of the formula:
where: 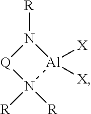
each X independently comprises a halide;
each R independently comprises at least one of an alkyl, a cycloalkyl, an aryl, or any combination thereof; and
Q comprises —(CR¹R¹)ₙ—,
where:
each R′ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
n is 1 to 10.

2. The composition of claim 1, wherein the composition does not comprise a pyrophoric compound.

3. The composition of claim 1, wherein the precursor compound is present as a liquid at temperatures in a range of 10° C. to 200° C.

4. The composition of claim 1, wherein the precursor compound is present in the composition at a purity of 95% to 99.999% as measured by 1H NMR.

5. The composition of claim 1, wherein the precursor compound comprises a compound of the formula: 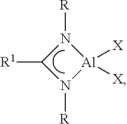
where:
X independently comprises a halide;
each R comprises at least one of an alkyl, a cycloalkyl, an aryl, or any combination thereof; and
R¹ comprises at least one of an alkyl, a cycloalkyl, an aryl, an amino, or any combination thereof.

6. The composition of claim 1, wherein the precursor compound comprises a compound of the formula: 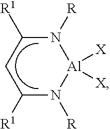
where:
each X independently comprises a halide;
each R independently comprises at least one of an alkyl, a cycloalkyl, an aryl, or any combination thereof; and
each R¹ independently comprises at least one of an alkyl, a cycloalkyl, an aryl, or any combination thereof.

7. A composition comprising:
a precursor compound of the formula: 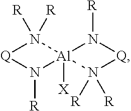
where:
X comprises a halide;
each R independently comprises at least one of an alkyl, a cycloalkyl, an aryl, or any combination thereof; and
each Q independently comprises —(CR¹R¹)ₙ—,
where:
each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
n is 1 to 10.

8. The composition of claim 7, wherein the composition does not comprise a pyrophoric compound.

9. The composition of claim 7, wherein the precursor compound is present as a liquid at temperatures in a range of 10° C. to 200° C.

10. The composition of claim 7, wherein the precursor compound is present in the composition at a purity of 95% to 99.999% as measured by 1H NMR.

11. The composition of claim 7, wherein the precursor compound comprises a compound of a formula: 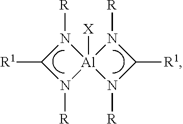
where:
X comprises a halide;
each R independently comprises at least one of an alkyl, a cycloalkyl, an aryl, or any combination thereof; and
each R¹ independently comprises at least one of an alkyl, a cycloalkyl, an aryl, an amino, or any combination thereof.

12. The composition of claim 7, wherein the precursor compound comprises a compound of the formula: 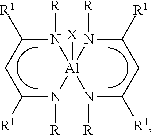
where:
X comprises a halide;
each R independently comprises at least one of an alkyl, a cycloalkyl, an aryl, or any combination thereof; and
each R¹ independently comprises at least one of an alkyl, a cycloalkyl, an aryl, or any combination thereof.

13. A method comprising:
obtaining a precursor compound,
wherein the precursor compound comprises a compound of the formula: 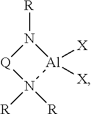
where:
X independently comprises a halide;
each R independently comprises at least one of an alkyl, a cycloalkyl, an aryl, or any combination thereof; and
Q comprises —(CR¹R¹)ₙ—,
where:
each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
n is 1 to 10;
vaporizing at least the precursor compound to obtain a vaporized precursor; and
contacting a substrate with at least the vaporized precursor to form a film on the substrate.

14. The method of claim 13, wherein, prior to the step of vaporizing, the precursor compound is present as a liquid.

15. The method of claim 13, wherein the precursor compound comprises a compound of the formula: 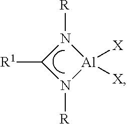
where:
each X independently comprises a halide;
each R comprises at least one of an alkyl, a cycloalkyl, an aryl, or any combination thereof; and
R¹ comprises at least one of an alkyl, a cycloalkyl, an aryl, an amino, or any combination thereof.

16. The method of claim 13, wherein the precursor compound comprises a compound of the formula: 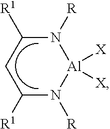
where:
each X independently comprises a halide;
each R independently comprises at least one of an alkyl, a cycloalkyl, an aryl, or any combination thereof; and
each R¹ independently comprises at least one of an alkyl, a cycloalkyl, an aryl, or any combination thereof.

17. A method comprising:
obtaining a precursor compound,
wherein the precursor compound comprises a compound of the formula: 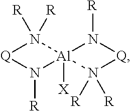
where:
X comprises a halide;
each R independently comprises at least one of an alkyl, a cycloalkyl, an aryl, or any combination thereof; and
each Q independently comprises —(CR¹R¹)ₙ—,
where:
each R¹ independently comprises at least one of a hydrogen, an alkyl, a cycloalkyl, an aryl, an amino, or any combination thereof, or at least two R¹s are bonded to form at least one of a cycloalkyl, an aromatic ring, or any combination thereof; and
n is 1 to 10;
vaporizing at least the precursor compound to obtain a vaporized precursor; and
contacting a substrate with at least the vaporized precursor to form a film on the substrate.

18. The method of claim 17, wherein, prior to the step of vaporizing, the precursor compound is present as a liquid.

19. The method of claim 17, wherein the precursor compound comprises a compound of a formula: 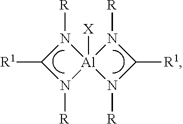
where:
X comprises a halide;
each R independently comprises at least one of an alkyl, a cycloalkyl, an aryl, or any combination thereof; and
each R¹ independently comprises at least one of an alkyl, a cycloalkyl, an aryl, an amino, or any combination thereof.

20. The method of claim 17, wherein the precursor compound comprises a compound of the formula: 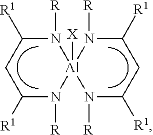
where:
X comprises a halide;
each R independently comprises at least one of an alkyl, a cycloalkyl, an aryl, or any combination thereof; and
each R¹ independently comprises at least one of an alkyl, a cycloalkyl, an aryl, or any combination thereof.
